(19) United States
(12) Patent Application Publication
(10) Pub. No.: US 2012/0032898 A1
(43) Pub. Date: Feb. 9, 2012

(54) PROJECTED CAPACITIVE TOUCH PANEL AND FABRICATION METHOD THEREOF

(75) Inventors: Chi-Chen Li, Kaohsiung City (TW); Fu-Cheng Huang, Kaohsiung City (TW)

(73) Assignee: ARIMA DISPLAY CORPORATION, Kaohsiung City (TW)

(21) Appl. No.: 13/012,186

(22) Filed: Jan. 24, 2011

(30) Foreign Application Priority Data
Aug. 5, 2010 (TW) 099126165

(51) Int. Cl. G06F 3/041; B05D 5/12; B05D 3/06; G03F 7/20

(52) U.S. Cl. 345/173; 430/320; 427/58; 427/558

(57) ABSTRACT

A projected capacitive touch panel and fabrication method thereof is provided. The method includes steps of: (a) providing a substrate; (b) forming a conductive layer on the first plane of the substrate, wherein the conductive layer has a first pattern and a second pattern; and (c) forming a conductive bridge on the conductive layer to electrically connect the first pattern with the second pattern.

### FIELD OF THE INVENTION

The present invention relates to a touch panel and fabrication method thereof, more particularly to a projected capacitive touch panel and fabrication method thereof.

### BACKGROUND OF THE INVENTION

The projected capacitive touch panel is constructed by adding two sets of transparent traces (X, Y) being perpendicular to each other in two different planes and driver lines on the traditional capacitive touch panel. The prior arts related to the present invention could be referred to the following description or Taiwan patent application No. 098122986 filed by the present applicant.

Please refer to FIG. 1, which is a flow chart showing the method of manufacturing the prior capacitive touch panel. The prior manufacturing workflow 100 includes the following steps:

Step 101: An one side ITO (Indium Tin Oxide)-coated glass substrate is provided.

Step 102: A photoresist (A) is coated on the ITO layer and then the following processes of exposing, developing, etching and stripping are performed on the photoresist (A) layer in sequence, so that a Y-axis channel without Y-axis patterns is formed on the glass substrate as a first conductive layer. It is noted that a first photomask is utilized in the step 102.

Step 103: A photoresist (B) is coated on the first conductive layer and then the following processes of exposing, developing and post baking are performed on the photoresist (B) layer in sequence, so that an insulating layer (an insulating film) is formed on the central part of Y channel and part of the glass substrate to be the intersection point for separating X-axis channels from Y-axis channels. It is noted that a second photomask is utilized in the step 103.

Steps 104 and 105: An ITO layer is formed on the insulating layer by the Sputtering deposition, and then the following processes of exposing, developing, etching and stripping are performed in sequence after a photoresist (A) is coated on the ITO layer in order to form a X-axis pattern with a X-axis channel and a Y-axis pattern as a second conductive layer. It is noted that a third photomask is utilized in the steps 105.

Step 106: A metal layer is formed on the second conductive layer by the Sputtering deposition, and then the following processes of exposing, developing, etching and stripping are performed in sequence after a photoresist (A) is coated on the metal layer in order to form a metal-trace layer. It is noted that a forth photomask is utilized in the step 106.

Step 107: An ITO layer is formed on the back side (without an ITO layer) of the glass substrate by the Sputtering deposition as a shield for electromagnetic interference. Finally, the formed projected capacitive touch panel is proceeding to the following procedures of trace-inspection, breaking and so on, in order to finish the product.

Please refer to FIG. 2, which is a diagram showing the schematic drawing of the layered structures corresponding to FIG. 1. The schematic drawing of the layered structures is illustrated with the illustration of FIG. 1. Referring to FIG. 2, the layered structures of the projected capacitive touch panel designate in order of the substrate 201, the first conductive layer 202, the insulation layer 203, the second conductive layer 204, the metal conductive layer 205, the top-coating layer 206 and the shield layer 207 disposed on the opposite side of the substrate 201.

Please refer to FIGS. 3(a)-(g), which are diagrams showing the structure drawings of the projected capacitive touch panel in the first preferred embodiment corresponding to FIG. 1. The structure drawings of FIGS. 3(a)-(g) are illustrated with the illustration of FIG. 1. Referring to FIGS. 3(a) and (b), the first conductive layer 302 (as Y channel) made of a transparent conductive material such as ITO is formed on the substrate 301. Referring to FIGS. 3(c) and (d), the insulation layer 303 between X channel and Y channel is formed at an intersection portion of X channel and Y channel, and covers the central part of Y channel and part of the substrate 301 as shown in G-G′ cross-section. Referring to FIG. 3(e), the second conductive layer 304 (including X channel, X pattern and Y pattern) made of a transparent conductive material such as ITO is formed on the substrate 301, the first conductive layer 302 and the insulation layer 303. Accordingly, X pattern and Y pattern are interconnected with X channel and Y channel, respectively, which are separate by the insulation layer 303. Referring to FIGS. 3(f) and 3(g), H-H′ cross-section and I-I′ cross-section illustrate that the second conductive layer 304 is divided into the first part 3041 with X channel and X pattern and the second part 3042 with Y pattern. Referring to H-H′ cross-section, the insulation layer 303 covers the first conductive layer 302 and the first part 3041 with X channel and X pattern covers the insulation layer 303. Referring to I-I′ cross-section, the insulation layer 303 covers the central part of the first conductive layer 302, and the second part 3042 with Y pattern electrically connects with the first conductive layer 302.

The prior process of the above-mentioned projected capacitive touch panel has the following disadvantages:

1. The high manufacturing expenses and the low the process yield: Four photomasks are required during the process of the product.

2. The lowed sensitivity of sensor: The high resistance appears at the end of the ITO bridge which is used to bridge two Y patterns so that the sensitivity of sensor is lowed.

3. ITO circuit on the surface of the panel facilitates a short circuit and/or a broken circuit: The shattered glasses possibility scatter over ITO surface during the process of Scribing and Breaking the glass substrate, so that a short circuit and/or a broken circuit would occur in ITO circuit.

4. The risen resistance at the end of the Al—Nd trace: The conducting trace made of Al—Nd would be easily oxidized due to the moisture, which leads to increase the resistance at the end of the Al—Nd trace.

Therefore, the inventor thought of the idea of an improvement invention after considering the shortage of the prior art and finally invented the case of the “projected capacitive touch panel and fabrication method thereof”.

### SUMMARY OF THE INVENTION

The present invention provides a projected capacitive touch panel and fabrication method thereof. The projected capacitive touch panel has a first plane and a second plane, a conductive layer consisted of a first pattern, a second pattern and a third pattern disposed on the first plane, an insulation layer is formed on part of the conductive layer and part of the substrate, a metal bridge which is disposed on the central line of the insulation layer is used to electrically connect the first pattern and the second pattern, a shiled layer is disposed on the second plane, a top-coating layer is disposed on the insulation layer and covers the metal bridge, and a peel-off mask layer is disposed on the top-coating layer.

Preferably, according to the aspect of the present invention, the substrate is the glass substrate.

Preferably, according to the aspect of the present invention, the materials of the conducting layer and the shiled layer are ITO.

Preferably, according to the aspect of the present invention, the first pattern and the second pattern with a shape of diamond are arranged along X axis, and the conductive layer further includes a third pattern consisting of two diamond patterns connected with a Y channel, the first pattern, the second pattern and the third pattern provide a complementary configuration and arranged in an array.

Preferably, according to the aspect of the present invention, the metal bridge and a metal trace are disposed on the conductive layer. The metal bridge is used to electrically connect the first pattern and the second pattern.

Preferably, according to the aspect of the present invention, the material of the metal bridge and the metal trace is Mo—Al—Mo alloy.

Preferably, according to the aspect of the present invention, the material of the top-coating layer is SiO₂.

Preferably, according to the aspect of the present invention, the peel-off mask consists of Epoxy.

From the above descriptions, the present invention also discloses a method for manufacturing a projected capacitive touch panel, including the following steps: (a) a substrate is provided, (b) a conductive layer with a first pattern, a second pattern and a third pattern is formed on a first plane; and (c) a conductive bridge is disposed on the third pattern, which electrically connects the first pattern and the second pattern and separates from the third pattern.

Preferably, according to the above-mentioned fabrication method of the present invention, after step (c), further comprising the steps of: (d) an insulation layer is formed on the conductive layer, (e) a photoresist layer is formed on the ITO shield layer disposed on a second plane of the substrate, (f) a SiO₂ layer is formed on the conductive layer having the conductive bridge on it, and then a UV curing process is operated to cure it so as to form a top-coating layer, (g) an Epoxy layer is formed on the top-coating layer, and then a LTV curing process is operated to cure it so as to form a peel-off mask, (h) Trace-inspection is performed on the projected capacitive touch panel, (i) cutting the projected capacitive touch panel and (j) removing the peel-off mask before adhering cover lens on the projected capacitive touch panel.

Preferably, according to the above-mentioned fabrication method of the present invention, further comprising in the step (a): (a1) an ITO substrate with a first plane and a second plane is provided.

Preferably, according to the above-mentioned fabrication method of the present invention, further comprising in the step (b): (b1) a photoresist layer is coated on the first layer of the substrate, and then a first Exposure and Development process is performed on it; and (b2) a first Stripping process of peeling off the photoresist layer is performed after a first Etching process of etching a surface of the SiO₂ layer so as to pattern the conductive layer on the first plane, wherein the conductive layer further includes the first pattern and the second pattern with a shape of diamond and the third pattern consisting of two diamond patterns connected with a Y channel.

Preferably, according to the above-mentioned fabrication method of the present invention, further comprising in the step (d): (d1) an insulation material is coated on the conductive layer, and then a second Exposure and Development process is performed on it so as to pattern the insulation layer; and (d2) a Baking process is performed so that the insulation layer tightly adheres to the conductive layer.

The foregoing and other features and advantages of the present invention will be more clearly understood through the following descriptions with reference to the drawings, wherein:

### BRIEF DESCRIPTION OF THE DRAWINGS

FIG. 1 is a flow chart of the manufacturing process of the prior projected capacitive touch panel;

FIG. 2 is a schematic diagram of the layered structures of the prior projected capacitive touch panel, corresponding to the manufacturing process of FIG. 1;

FIGS. 3(a) to 3(g) are the structural drawings of the present application, corresponding to FIG. 1;

FIG. 4 is a flow chart of the manufacturing process of the present application;

FIG. 5 is a schematic diagram of the layered structures of the present application, corresponding to the manufacturing process of FIG. 4; and

FIGS. 6(a) to 6(h) are the structural drawings of the preferable embodiment of the present application, corresponding to FIG. 4.

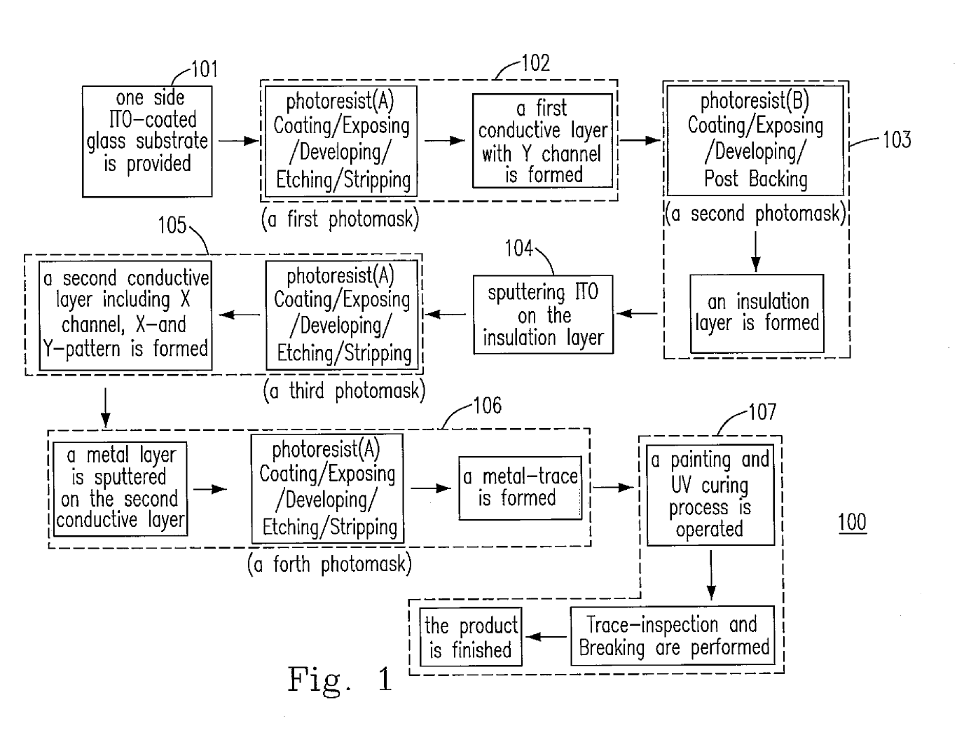

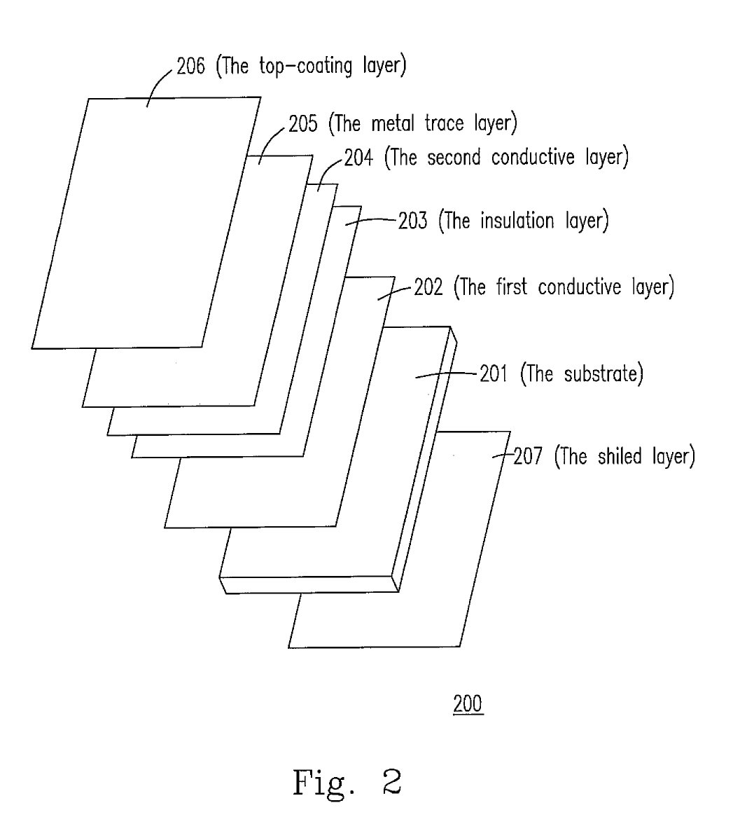

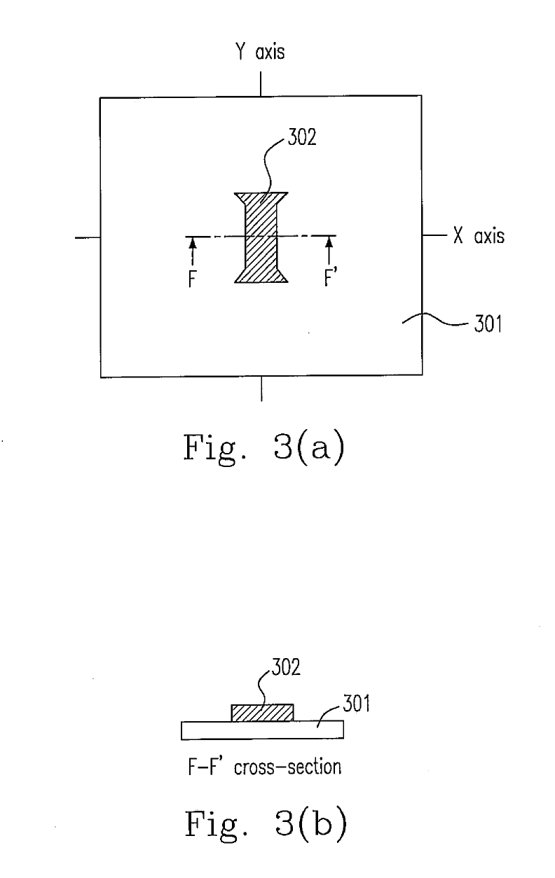

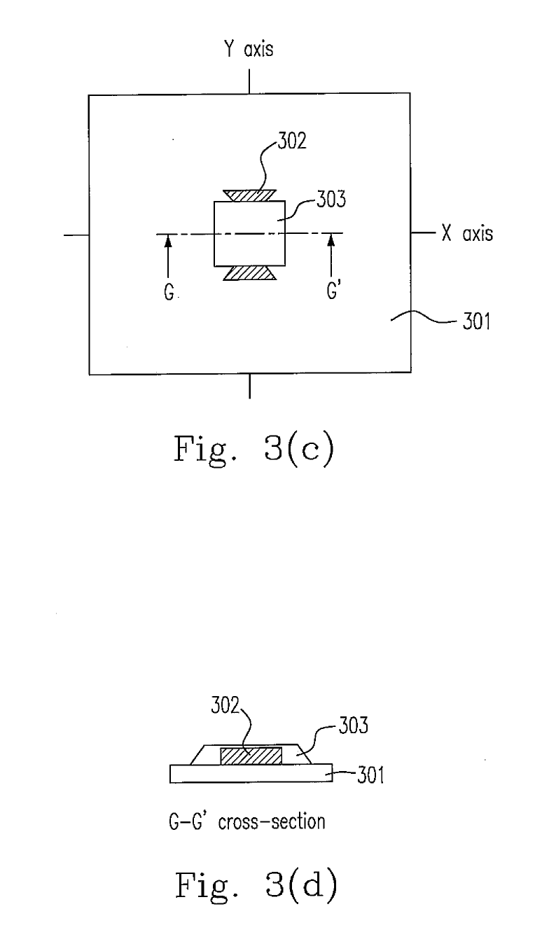

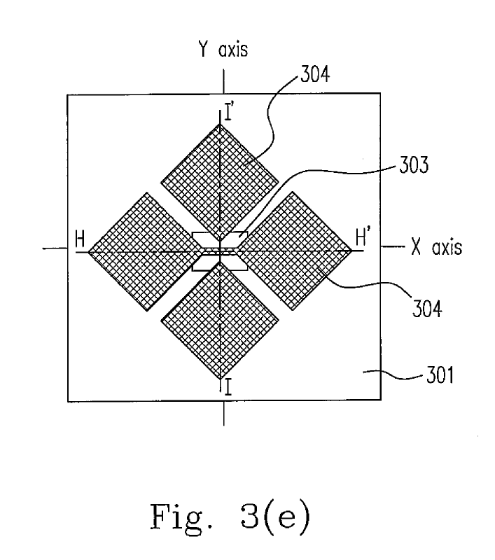

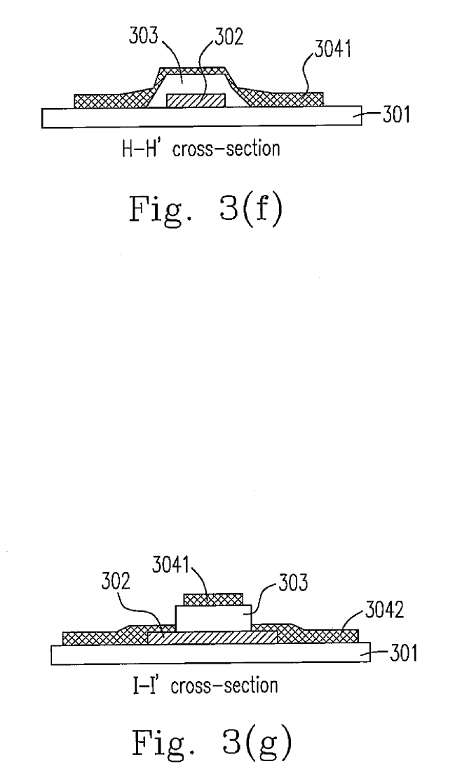

### DETAILED DESCRIPTION OF THE PREFERRED EMBODIMENT

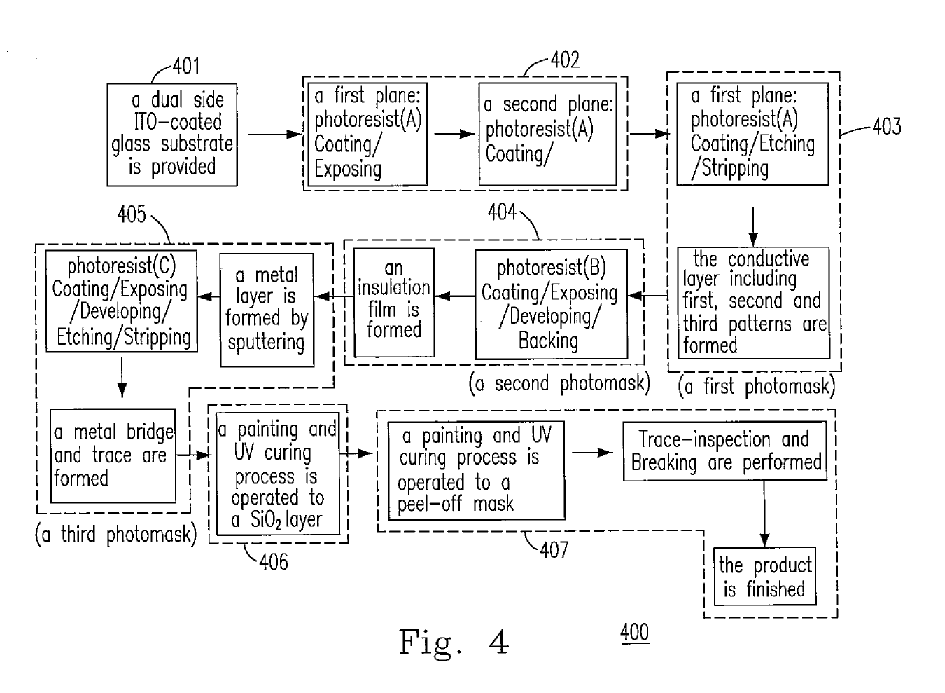

Please refer to FIG. 4, which is a flow chart of the manufacturing process of the present application. The manufacturing process of the present application 400 includes the following steps:

Step 401: A dual side ITO-coated substrate having a first plane and a second plane is provided, in which the substrate is preferable the glass substrate.

Step 402: A photoresist (A) is coated on the first plane so as to form a first photoresist layer, and then the Exposure process is performed on the first photoresist layer. A photoresist (A) is coated on the second plane so as to form a second photoresist layer in order to protect the ITO layer on the second plane.

Step 403: The processes of developing, etching and stripping are performed in sequence on the first plane so as to form a conductive layer having a first pattern, a second pattern and a third pattern. It is noted that a first photomask is utilized in the step 403.

Step 404: A photoresist insulation material (B) is coated on the conductive layer by the Sputtering deposition so as to form an insulation layer, and then the second Exposure and Development process (including Exposure, Development, Etching and Stripping) is performed on the insulation layer in order to form an insulating film on the central part of Y channel and part of the glass substrate as the intersection points to separate X-axis channels from Y-axis channels. Afterwards, a Baking process is performed so that the insulation layer tightly adheres to the conductive layer. It is noted that a second photomask is utilized in the step 404.

Step 405: A metal layer is sputtered on the insulation layer by the Sputtering deposition, and then the following processes of Exposure, Development, Etching and Stripping are performed in sequence after a photoresist (C) is coated on the metal layer in order to form the metal bridge and the metal trace. It is noted that a third photomask is utilized in the step 405.

Step 406: A SiO₂ layer is formed on the conductive layer having the conductive bridges and the metal traces on it, and then a painting and UV curing process is operated to the SiO₂ layer so as to form an insulating top-coating layer.

Step 407: After forming an Epoxy layer on the top-coating layer, a painting and UV curing process is operated to the Epoxy layer so as to form a peel-off mask, and then the formed projected capacitive touch panel is proceeding to the following procedures of Trace-inspection, Breaking, Cutting and so on. Finally, the peel-off mask is removed before adhering cover lens on the projected capacitive touch panel to finish the product.

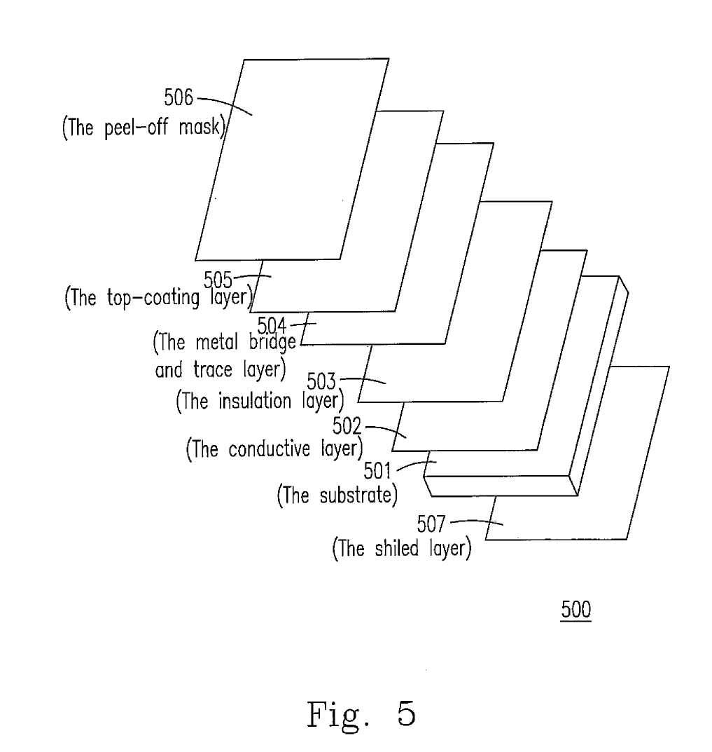

Please refer to FIG. 5, it is the schematic drawing of the layered structures of the present application, corresponding to the manufacturing process of FIG. 4. The schematic drawing of the layered structures of FIG. 5 is illustrated with the illustration of FIG. 4. Referring to FIG. 5, the layered structures of the projected capacitive touch panel designate in order of the substrate 501, the conductive layer 502, the insulation layer 503, the metal bridge and trace layer 504, the top-coating layer 505, the peel-off mask 506 and the shiled layer 507 disposed on the second plane of the substrate 501.

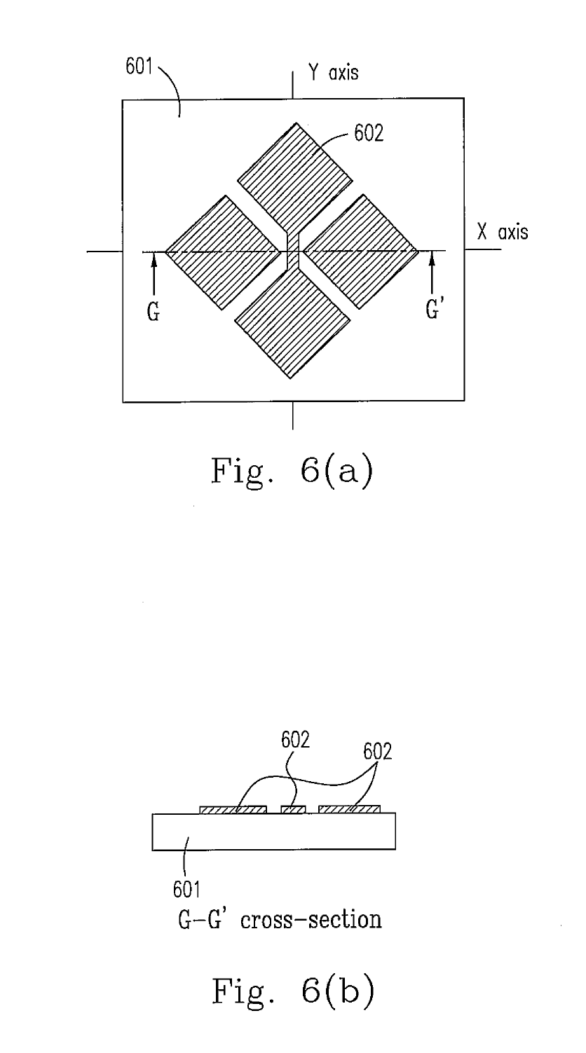

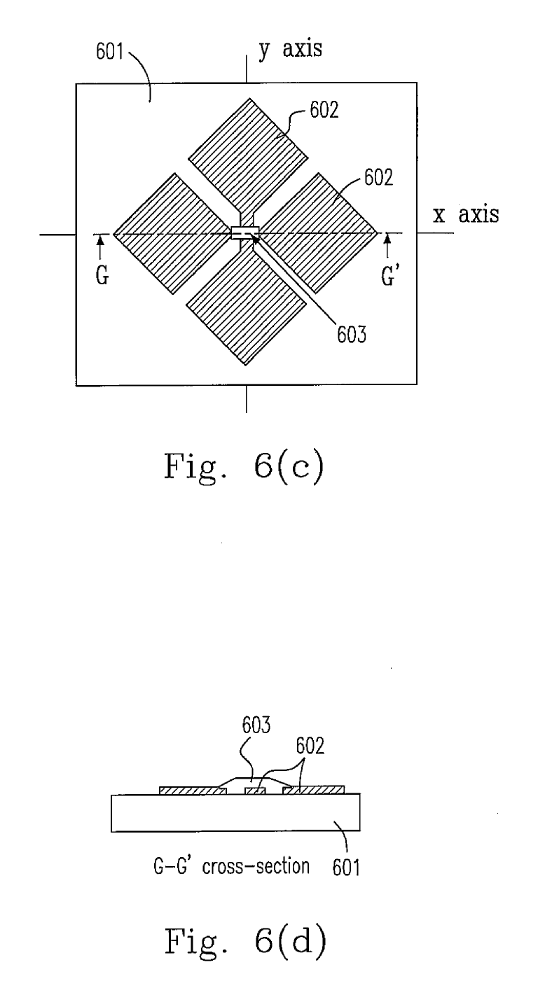

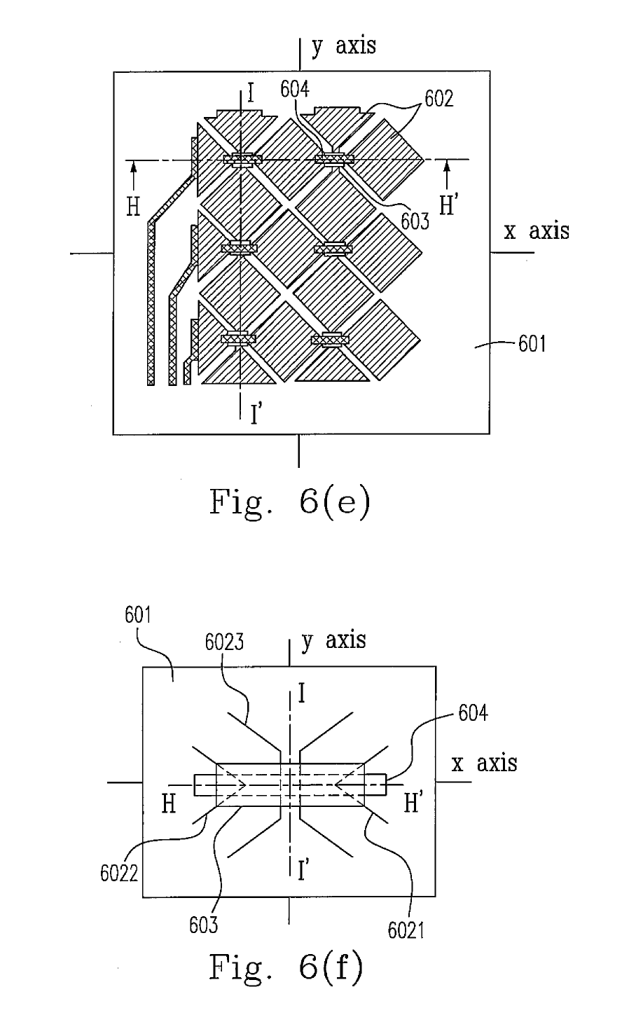

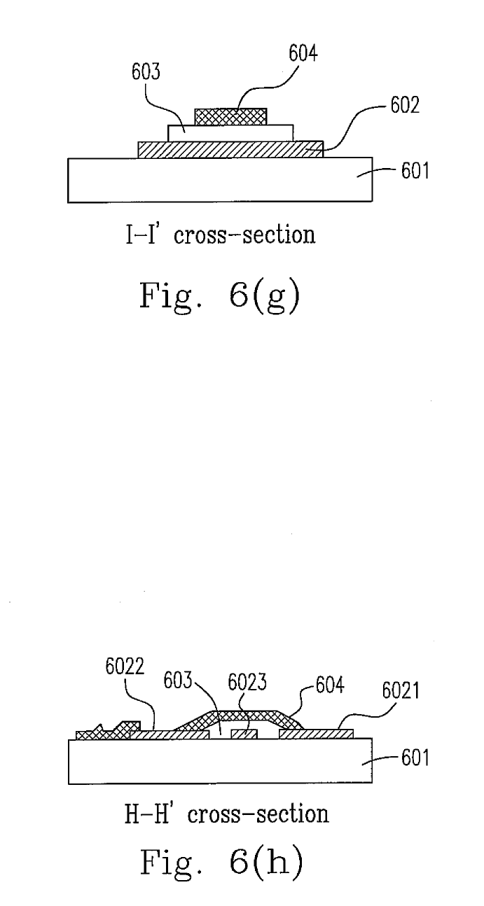

Please refer to FIGS. 6(a)-(h), which are the structure drawings of the projected capacitive touch panel in the preferred embodiment corresponding to FIG. 4. The structure drawings of FIGS. 6(a)-(g) are illustrated with the illustration of FIG. 4. Referring to FIGS. 6(a) and (b), they are the illustrations of the first pattern, the second pattern and the third pattern formed on the substrate 601, viewing from the face side and the lateral side. The conductive layer 602, preferably made of a transparent conductive material such as ITO, consists of the first pattern, the second pattern and the third pattern which is formed on the substrate 601. In the embodiment, the first pattern and the second pattern are definite to two diamond patterns arranged along the direction of X axis, and the third pattern is limited to the dumbbell-shaped pattern configured along the direction of Y axis. However, the patterns or figures mentioned in the preferred embodiment can be denominated or defined by the person in the skilled art at will, and are not limited by the above-mentioned. Referring to FIGS. 6(c) and (d), they are the illustrations of the insulation film 603 formed on the conductive layer 602, viewing from the face side and the lateral side. The insulation film 603 locates at an intersection point of X axis and Y axis, and covers the central part of Y channel, part of X pattern 602 and part of the substrate 601 as shown in G-G′ cross-section. Referring to FIG. 6(e), it is the illustration of the metal bridge 604 formed on both the conductive layer 602 and the insulation layer 603. Preferably, the material of the metal bridge 604 is Mo—Al—Mo alloy. Accordingly, the metal bridge 604 and the third pattern of the conductive layer 602 are separate by the insulation layer 603. Referring to FIGS. 6(f), (g) and (h), they are the illustrations of the intersection point structure of X axis and Y axis from three different aspects. H-H′ cross-section and I-I′ cross-section illustrate the structure of the overlapping part at the intersection point of X axis and Y axis. FIG. 6(f) shows that the conductive layer 602 is divided into three parts of the first pattern 6021, the second pattern 6022 and the third pattern 6023. Both of the first pattern 6021 and the second pattern 6022 arranged along the direction of X axis have the shape of a diamond, and the third pattern 6023 arranged along the direction of Y axis consists of two diamond patterns connected with a Y channel. Referring to FIG. 6(f) and I-I′ cross-section in FIG. 6(g), the insulation layer 603 covers the central part of Y channel of the third pattern 6023, which is insulated the metal bridge 604 from the third pattern 6023. Referring to FIG. 6(f) and H-H′ cross-section in FIG. 6(h), the insulation layer 603 covers the central part of Y channel of the third pattern 6023, part of the first pattern 6021 and part of the second pattern 6022. The first pattern 6021 is electrically connected with the second pattern 6022 through the metal bridge 604. And the insulation layer 603 is insulated the metal bridge 604 from the third pattern 6023, so that the electric leakage between the first pattern 6021, the second pattern 6022 and the metal bridge 604 will be averted. Therefore, the sensitivity of the projected capacitive touch panel will not be affected and maintain the high sensitivity. The above description and illustration should be considered to expound the structure of the preferred embodiment, so that a person having an ordinary skill in the art would embody the present invention according to it.

Through the above description, the invention of “a projected capacitive touch panel and fabrication method thereof” is provided. An ITO coating film (i.e. the conductive layer 602) including the first pattern 6021, the second pattern 6022 and the third pattern 6023 is formed on the substrate 601 by taking one time of a coating process instead of taking twice time of coating processes as the prior art did. Thus, the film color of the ITO film will be identical without the chromatic aberration form two coated layers, and the used times of the coating process could be reduced. Then, the touch panel structure of the present invention is a single layer structure except that located at the central part of Y channel is a triple layer structure including Y channel, the insulation layer 603 and the metal bridge 604, so that the optical isolation of the touch panel decreases and the surface transmittance of the touch panel increases. Then, in order to decrease the loop resistance of the touch panel, the present invention employs Mo—Al—Mo alloy as the material of the metal trace instead of Aluminum alloy to avoid the descended electric conductivity from the effect of the moisture. In addition, the metal bridge is made of Mo—Al—Mo alloy as well, so that the resistance at the contact of the metal trace and the metal bridge will be decreased due to the same Mo—Al—Mo material. Then, to avoid the short circuit in ITO patterns of the first plane, the present invention can use the photoresist insulation material to be micro-etching to form the insulation layer, so that the area and the position of the insulation layer can become narrower and more precise, respectively. Moreover, the peel-off mask can be coated on the insulation layer as the description of the present invention in order to avoid the shattered glasses possibility scatter over ITO surface during the process of Scribing and Breaking the glass substrate, so that a short circuit and/or a broken circuit would occur in ITO circuit. Therefore, according to the above description, the yield rate of the product is great improved, which leads the present invention to be patentable.

Although the present invention has been described and illustrated in an example of the most preferred embodiment, the constructional characteristics of the present invention are not limited by that. The variations and modifications that anyone who is familiar with the skill can think of easily which fall within the spirit and scope of the present invention as defined by the appended claims should be included.

What is claimed is:

1. A touch panel, comprising:
a substrate includes a first plane;
a conductive layer includes a first pattern and a second pattern disposed on the first plane;
an insulation layer is deposed on the conductive layer; and
a metal bridge is disposed on the conductive layer in order to electrically connect the first pattern and the second pattern.

2. The touch panel as claimed in claim 1, further comprising:
a shiled layer is disposed on the second plane;
a top-coating layer is disposed on the insulation layer; and
a peel-off mask layer is disposed on the top-coating layer.

3. The touch panel as claimed in claim 1, wherein the material of the substrate is glass, the materials of the conducting layer and the shiled layer are ITO, the insulation layer consists of the photoresist insulation material, the material of the top-coating layer is SiO₂, the material of the peel-off mask is Epoxy.

4. The touch panel as claimed in claim 1, wherein the first pattern and the second pattern with a shape of diamond are arranged along X axis, and the conductive layer further includes a third pattern consisting of two diamond patterns connected with a Y channel, the first pattern, the second pattern and the third pattern provide a complementary configuration and arranged in an array.

5. The touch panel as claimed in claim 1, wherein the metal bridge consisting of Mo—Al—Mo alloy has a dielectric coefficient less than the dielectric coefficient of the patterns.

6. A method for manufacturing a touch panel, comprising the steps of:
(a) a substrate is provided;
(b) a conductive layer with a first pattern and a second pattern is formed on a first plane; and
(c) a conductive bridge connected the first pattern and the second pattern is formed on the conductive layer.

7. A method for manufacturing a touch panel according to claim 6, after step (c), further comprising the steps of:
(d) an insulation layer is formed on the conductive layer;
(e) a photoresist layer is formed on the ITO shield layer disposed on a second plane of the substrate;
(f) a SiO₂ layer is formed on the conductive layer having the conductive bridge on it, and then a UV curing process is operated to cure it so as to form a top-coating layer; and
(g) an Epoxy layer is formed on the top-coating layer, and then a UV curing process is operated to cure it so as to form a peel-off mask.

8. A method for manufacturing a touch panel according to claim 6, further comprising in the step (a):
(a1) an ITO substrate with a first plane and a second plane is provided.

9. A method for manufacturing a touch panel according to claim 6, further comprising in the step (b):
(b1) a photoresist layer is coated on the first layer of the substrate, and then a first Exposure and Development process is performed on it; and
(b2) a first Stripping process of peeling off the photoresist layer is performed after a first Etching process of etching a surface of the SiO₂ layer so as to pattern the conductive layer on the first plane, wherein the conductive layer further includes the first pattern and the second pattern with a shape of diamond and the third pattern consisting of two diamond patterns connected with a Y channel.

10. A method for manufacturing a touch panel according to claim 7, further comprising in the step (d):
(d1) an insulation material is coated on the conductive layer, and then a second Exposure and Development process is performed on it so as to pattern the insulation layer; and
(d2) a Baking process is performed so that the insulation layer tightly adheres to the conductive layer.
